(19) United States
(12) Patent Application Publication
(10) Pub. No.: US 2024/0302745 A1
(43) Pub. Date: Sep. 12, 2024

(54) RESIST UNDERLAYER FILM-FORMING COMPOSITION CONTAINING POLYMER HAVING ALICYCLIC HYDROCARBON GROUP

(71) Applicant: NISSAN CHEMICAL CORPORATION, Tokyo (JP)

(72) Inventors: Shou SHIMIZU, Toyoma-shi (JP); Mamoru TAMURA, Toyoma-shi (JP)

(73) Assignee: NISSAN CHEMICAL CORPORATION, Tokyo (JP)

(21) Appl. No.: 18/271,390

(22) PCT Filed: Jan. 25, 2022
(86) PCT No.: PCT/JP2022/002501

§ 371 Date: Jul. 7, 2023

(30) Foreign Application Priority Data
Jan. 26, 2021 (JP) 2021-010376

(51) Int. Cl. G03F 7/11; C08F 220/18; C08F 220/28

(52) U.S. Cl. CPC G03F 7/11; C08F 220/1811; C08F 220/283

(57) ABSTRACT

A composition for forming a resist underlayer film that enables the formation of a desired resist pattern; a method for producing a resist pattern and a method for producing a semiconductor device, each of which uses the composition for forming a resist underlayer film. This composition for forming a resist underlayer film contains a polymer and a solvent, the polymer including a unit structure (A) represented by formula (1)

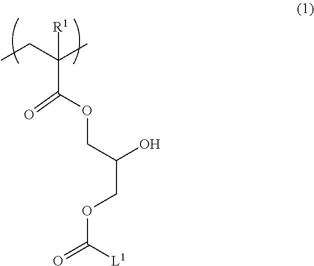

[in formula (1): R¹ represents a hydrogen atom or an alkyl group having 1-6 carbon atoms; and L¹ represents an optionally substituted aliphatic ring, an aryl group having 6-40 carbon atoms or a hetero ring] and a unit structure (B) that contains an aliphatic ring in a side chain and that is different from the unit structure (A).

### TECHNICAL FIELD

The present invention relates to a composition used in a lithography process, particularly in a leading-edge (for example, ArF, EUV, or EB) lithography process, for semiconductor production. The present invention also relates to the application of a resist underlayer film from the composition to a method for producing a resist-patterned substrate and to a method for manufacturing a semiconductor device.

### BACKGROUND ART

The manufacturing of semiconductor devices has conventionally involved lithographic microprocessing using a resist composition. In the microprocessing, a thin film of a photoresist composition is formed on a semiconductor substrate, such as a silicon wafer, and is irradiated with an active ray, such as ultraviolet light, through a mask pattern for drawing a device pattern. The latent image is then developed, and the substrate is etched while using the thus-obtained photoresist pattern as a protective film, thereby forming fine irregularities corresponding to the pattern on the substrate surface. Active rays of conventional choice are i-ray (365 nm wavelength), KrF excimer laser beam (248 nm wavelength), and ArF excimer laser beam (193 nm wavelength). In addition, EUV light (13.5 nm wavelength) and EB (electron beam) are studied for practical use in the leading-edge microprocessing due to the recent increase in the packing density of semiconductor devices. A growing problem along with this trend is that a resist pattern cannot be formed as designed due to influence from, for example, a semiconductor substrate. An approach that has widely been studied to solve the above problem is to provide a resist underlayer film between a resist and a semiconductor substrate.

Patent Literature 1 discloses a resist underlayer film-forming composition that includes a polymer including a specific unit structure and a unit structure having a crosslinking site. Patent Literature 2 discloses a photoresist underlayer film material that includes a copolymer of a hydroxyl-containing vinyl naphthalene and a hydroxyl-free olefin.

### CITATION LIST

### Patent Literature

Patent Literature 1: WO 2012/017790
Patent Literature 2: JP 2007-171895 A

### SUMMARY OF INVENTION

### Technical Problem

For example, the properties required of resist underlayer films are that the resist underlayer film is not intermixed with a resist film formed on top thereof (is insoluble in a resist solvent) and that the dry etching rate is higher than that of a resist film.

In EUV lithography, the line width of a resist pattern that is formed is 32 nm or less. Thus, a resist underlayer film for EUV exposure is formed with a smaller film thickness than conventional. Such a thin film is hardly uniform and tends to have defects, such as pinholes and aggregations, due to the influence of, for example, the substrate surface and the polymer that is used.

Meanwhile, a resist pattern is formed by a negative development process in which a resist film is treated with a solvent, usually an organic solvent, capable of dissolving the resist film to remove unexposed portions of the resist film, thus leaving the exposed portions of the resist film as a resist pattern, or by a positive development process in which exposed portions of the resist film are removed to leave unexposed portions of the resist film as a resist pattern. In these development steps, the major challenge resides in improving the adhesion of the resist pattern.

Furthermore, there are demands that a resist pattern should be formed with a good rectangular shape while reducing or eliminating the deterioration in LWR (line width roughness, variation (roughness) in line width) at the time of resist pattern formation, and the resist sensitivity should be enhanced.

Objects of the present invention are to provide a composition for forming a resist underlayer film that allows a desired resist pattern to be formed, and to provide a resist pattern forming method using the resist underlayer film-forming composition, thereby solving the problems discussed above.

### Solution to Problem

The present invention embraces the following.
[1]
A resist underlayer film-forming composition comprising a polymer and a solvent, the polymer comprising a unit structure (A) represented by formula (1) below and a unit structure (B) containing an aliphatic ring in a side chain and differing from the unit structure (A),

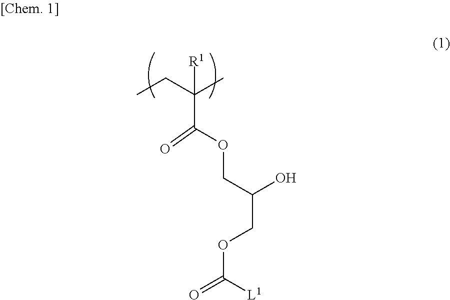

wherein, in formula (1), R¹ denotes a hydrogen atom or a C1-C6 (preferably C1-C5) alkyl group; and L¹ denotes an optionally substituted aliphatic ring, a C6-C40 aryl group, or a heterocyclic ring.
[2]
The resist underlayer film-forming composition according to [1], wherein the unit structure (B) is represented by formula (2) below:

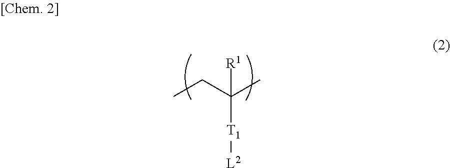

wherein, in formula (2), T¹ denotes a single bond, an amide bond, or an ester bond; and L² denotes an optionally substituted aliphatic ring.
[3]
The resist underlayer film-forming composition according to [1] or [2], wherein the polymer further comprises a unit structure (C containing a reactive substituent.
[4]
The resist underlayer film-forming composition according to any one of [1] to [3], wherein L¹ is an optionally substituted C₃-C₁₀ monocyclic or polycyclic aliphatic ring.
[5]
The resist underlayer film-forming composition according to any one of [2] to [4], wherein L² is an optionally substituted C3-C10 monocyclic or polycyclic aliphatic ring.
[6]
The resist underlayer film-forming composition according to any one of [1] to [5], further comprising an acid generator.
[7]
The resist underlayer film-forming composition according to any one of [1] to [6], further comprising a crosslinking agent.
[8]
A resist underlayer film, which is a baked product of a coating film of the resist underlayer film-forming composition according to any one of [1] to [7]
[9]
A method for producing a patterned substrate, comprising the steps of: applying the resist underlayer film-forming composition according to any one of [1] to [7] onto a semiconductor substrate and baking the applied composition to form a resist underlayer film;
applying a resist onto the resist underlayer film and baking the applied resist to form a resist film;
exposing the semiconductor substrate coated with the resist underlayer film and the resist; and
developing the exposed resist film, and performing patterning.
[10]
A method for manufacturing a semiconductor device, comprising the steps of:
forming on a semiconductor substrate a resist underlayer film of the resist underlayer film-forming composition according to any one of [1] to [7];
forming a resist film on the resist underlayer film;
forming a resist pattern by applying a light or electron beam to the resist film followed by development;
forming a pattern in the resist underlayer film by etching the resist underlayer film through the resist pattern formed; and
processing the semiconductor substrate through the pattern in the resist underlayer film.

### Advantageous Effects of Invention

The resist underlayer film-forming composition of the present invention has excellent applicability to a semiconductor substrate to be processed and exhibits excellent adhesion at an interface between a resist and a resist underlayer film in the formation of a resist pattern. Thus, a satisfactory rectangular resist pattern can be formed without separation of the resist pattern. In particular, the composition exhibits marked effects in EUV (13.5 nn wavelength) or EB (electron beam) exposure.

### BRIEF DESCRIPTION OF DRAWINGS

FIG. 1 is a result (a scanning electron micrograph) of observation from above a resist pattern of Example 1 in Examples [Formation of resist pattern with electron beam lithography system].

FIG. 2 is a result (a scanning electron micrograph) of observation from above a resist pattern of Example 2 in Examples [Formation of resist pattern with electron beam lithography system].

FIG. 3 is a result (a scanning electron micrograph) of observation from above a resist pattern of Example 3 in Examples [Formation of resist pattern with electron beam lithography system].

FIG. 4 is a result (a scanning electron micrograph) of observation from above a resist pattern of Example 4 in Examples [Formation of resist pattern with electron beam lithography system].

FIG. 5 is a result (a scanning electron micrograph) of observation from above a resist pattern of Comparative Example 1 in Examples [Formation of resist pattern with electron beam lithography system],

FIG. 6 is a result (a scanning electron micrograph) of observation from above a resist pattern of Comparative Example 2 in Examples [Formation of resist pattern with electron beam lithography system].

FIG. 7 is a result (a scanning electron micrograph) of observation from above a resist pattern of Comparative Example 3 in Examples [Formation of resist pattern with electron beam lithography system].

### DESCRIPTION OF EMBODIMENTS

### <Resist Underlayer Film-Forming Compositions>

A resist underlayer film-forming composition of the present invention contains a polymer and a solvent. The polymer includes a unit structure (A) represented by formula (1) below and a unit structure (B) containing an aliphatic ring in a side chain and differing from the unit structure (A),

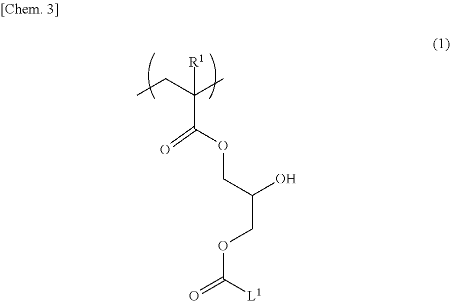

wherein, in formula (1) R¹ denotes a hydrogen atom or a C1-C6 (preferably C1-C5) alkyl group; and L¹ denotes an optionally substituted aliphatic ring, a C6-C40 aryl group, or a heterocyclic ring.

The polymer may be produced by a known method, such as the method described in Examples.

### <Unit Structure (A)>

The unit structure (A) in the present invention has a structure represented by the above formula (1).

Examples of the C1-C6 alkyl groups include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, i-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, and 3,3-dimethyl-cyclobutyl group.

The optionally substituted aliphatic ring indicates an aliphatic ring that may be substituted with, for example, a hydroxy group, a C1-C10 alkyl group, a C₁-C₂₀ alkoxy group, a C₁-C₁₀ acyloxy group, or a carboxyl group in place of all or part of the hydrogen atoms of the aliphatic ring.

Examples of the C1-C10 alkyl groups include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-Cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group, decyl group, undecyl group, dodecyl group, tridecyl group, tetradecyl group, pentadecyl group, hexadecyl group, heptadecyl group, octadecyl group, nonadecyl group, and eicodecyl group.

Examples of the C1-C20 alkoxy groups include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, 1-ethyl-2-methyl-n-propoxy group, cyclopentyloxy group, cyclohexyloxy group, norbornyloxy group, adamantyloxy group, adarantanemethyloxy group, adamantaneethyloxy group, tetracyclodecanyloxy group, and tricyclodecanyloxy group.

The C1-C10 acyloxy groups may be represented by formula (4) below:

[Chem. 4]

Z—COO—* Formula (4)

wherein, in formula (4), Z denotes a hydrogen atom, a C1-C9 alkyl group optionally substituted with the substituent mentioned hereinabove, or a C6-C40 aryl group optionally substituted with the substituent mentioned hereinabove; and * is a bond to the aliphatic ring. Specific examples of the C6-C40 aryl groups and the heterocyclic rings will be given later.

The aliphatic ring may be a C3-C10 monocyclic or polycyclic aliphatic ring.

Examples of the C3-C10 monocyclic or polycyclic aliphatic rings include cyclopropane, cyclobutane, cyclopentane, cyclohexane, cyclohexene, cycloheptane, cyclooctane, cyclononane, cyclodecane, spirobicyclopentane, bicyclo[2.1.0]pentane, bicyclo[3.2.1]octane, tricyclo[3.2.1.0^{2,7}]octane, spiro[3,4]octane, norbomane, norbornene, and tricyclo[3.3.1.1^{3,7}]decane (adamantane).

The polycyclic aliphatic ring is preferably a bicyclo ring or a tricyclo ring. Regarding such rings, the bicyclo rings may be exemplified by norbornane, norbornene, spirobicyclopentane, bicyclo[2.1.0]pentane, bicyclo[3.2.1]octane, and spiro[3,4]octane.

Regarding those rings mentioned above, the tricyclo rings may be exemplified by tricyclo[3.2.1.0^{2,7}]octane and tricyclo[3.3.1.1^{3,7}]decane (adamantane).

Examples of the C6-C40 aryl groups include phenyl group, o-methylphenyl group, in-methylphenyl group, p-methylphenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, and 9-phenanthryl group.

Examples of the heterocyclic rings include furan, thiophene, pyrrole, imidazole, pyran, pyridine, pyrimidine, pyrazine, pyrrolidine, piperidine, piperazine, morpholine, indole, purine, quinoline, isoquinoline, quinuclidine, chromene, thianthrene, phenothiazine, phenoxazine, xanthene, acridine, phenazine, carbazole, triazineone, triazinedione, and triazinetrione.

### <Unit Structure (B)>

The unit structure (B) is a unit structure that contains an aliphatic ring in a side chain and differs from the unit structure (A), and is not limited as long as the unit structure allows the polymer to achieve the advantageous effects of the subject application. The unit structure may be represented by formula (2) below:

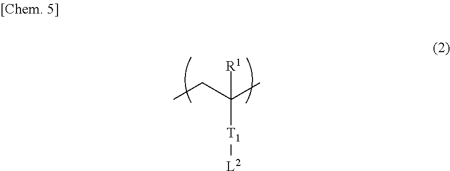

wherein, in formula (2), T₁ denotes a single bond, an amide bond, or an ester bond; and L² denotes an optionally substituted aliphatic ring.

The optionally substituted aliphatic ring is the same as mentioned hereinabove.

When L¹ in the unit structure (A) (formula (1)) is selected from optionally substituted aliphatic rings, the aliphatic ring selected is preferably one having the same structure as the aliphatic ring in the unit structure (B). In particular, a combination of adamantane is preferable.

### <Unit Structure (C)>

The polymer may further include a unit structure (C) containing a reactive substituent. Examples of the reactive substituents include hydroxy group, acyl group, acetyl group, formyl group, benzoyl group, carboxyl group, carbonyl group, amino group, imino group, cyano group, azo group, azide group, thiol group, sulfo group, and allyl group. Of these, hydroxy group is preferable.

Exemplary monomers suitable for forming the unit structure (C) containing a reactive substituent include 2-hydroxyethyl (meth)acrylate, 2-hydroxypropyl (meth)acrylate, 3-hydroxypropyl (meth)acrylate, and 4-hydroxybutyl (meth)acrylate. The term (meth)acrylate indicates both methacrylate and acrylate.

For example, the lower limit of the weight average molecular weight of the polymer is 500, 1,000, 2,000, or 3,000. For example, the upper limit of the weight average molecular weight of the reaction product is 30,000, 20,000, or 10,000.

For example, the molar ratio of the unit structure (A), the unit structure (B), and the unit structure (C) in the whole of the polymer is (unit structure (A)):(unit structure (B)):(unit structure (C))=(10-99):(1-70):(0-50).

### <Methods for Producing Polymers>

In a method for producing the polymer of the present invention, a (meth)acrylate monomer having a side chain structure of formula (1) may be used directly for polymerization. Alternatively, as described in Examples, a polymer precursor may be produced by reacting, for example, glycidyl methacrylate with a monomer for forming the unit structure (B) containing an aliphatic ring in a side chain, such as a compound represented by formula (2-1) below:

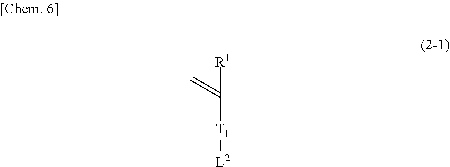

wherein, in formula (2-1), T₁ and L² are the same as defined hereinabove, and subsequently the polymer precursor may be reacted with an aliphatic ring-containing compound having a reactive substituent, such as adamantanecarboxylic acid, an aryl group-containing compound having a reactive substituent, such as benzoic acid or 4-methylsulfonebenzoic acid, or a heterocyclic ring-containing compound having a reactive substituent by a known method, thereby producing a polymer.

### <Solvent>

The solvent used in the resist underlayer film-forming composition of the subject application is not particularly limited as long as the solvent can uniformly dissolve the components that are solid at room temperature, such as the polymer mentioned above. Organic solvents generally used in semiconductor lithographic chemicals are preferable. Specific examples include ethylene glycol monomethyl ether, ethylene glycol monoethyl ether, methylcellosolve acetate, ethylcellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone. N,N-dimethylformamide, and N,N-dimethylacetamide. The solvents may be used each alone or in combination of two or more thereof.

Of the solvents mentioned above, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Acid Generator>

The resist underlayer film-forming composition of the present invention may include an acid generator as an optional component. Any thermal acid generators and photoacid generators may be used, with thermal acid generators being preferable. Examples of the thermal acid generators include sulfonic acid compounds and carboxylic acid compounds, such as p-toluenesulfonic acid, trifluoromethanesulfonic acid, pyridinium-p-toluenesulfonate (pyridinium-p-toluenesulfonic acid), pyridinium phenolsulfonic acid, pyridinium-p-hydroxybenzenesulfonic acid (pyridinium p-phenolsulfonate salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generators include onium salt compounds, sulfonimide compounds, and disulfonyldiazomethane compounds.

Examples of the onium salt compounds include iodonium salt compounds, such as diphenyliodorium hexafluorophosphate, diphenyliodonium trifluoromethanesulfonate, diphenyliodonium nonafluoro-n-butanesulfonate, diphenyiiodonium perfluoro-n-octanesuifonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoro-n-butanesulfonate, triphenylsulfonium camphorsulfonate, and triphenylsulfonium trifluoromethanesulfonate.

Examples of the sulfonimide compounds include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide.

Examples of the disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generators may be used each alone or in combination of two or more thereof.

When the acid generator is used, the content of the acid generator is, for example, within the range of 0.1% by mass to 50% by mass, and preferably 1% by mass to 30% by mass relative to a crosslinking agent given below.

### <Crosslinking Agent>

The resist underlayer film-forming composition of the present invention may include a crosslinking agent as an optional component. Examples thereof include hexamethoxymethylmelamine, tetramethoxymethylbenzoguananine, 1,3,4,6-tetrakis(methoxymethyl)glycoluril (tetramethoxymethylglycoltril) (POWDERLINK [registered trademark] 1174), 1,3,4,6-tetrakis(butoxymethyl)glycoluril, 1,3,4,6-tetrakis(hydroxymethyl)glycoluril, 1,3-bis(hydroxy methyl)urea, 1,1,3,3-tetrakis(butoxymethyl)urea, and 1,1,3,3-tetrakis(methoxymethyl)urea.

Furthermore, the crosslinking agents in the subject application may be nitrogen-containing compounds described in WO 2017/187969 that have in the molecule 2 to 6 substituents represented by formula (1d) below which are bonded to nitrogen atoms.

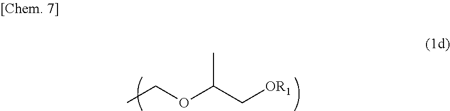

wherein, in formula (1d), R₁ denotes a methyl group or an ethyl group.

The nitrogen-containing compounds that have in the molecule 2 to 6 substituents represented by formula (1d) may be glycoluril derivatives represented by formula (1E) below:

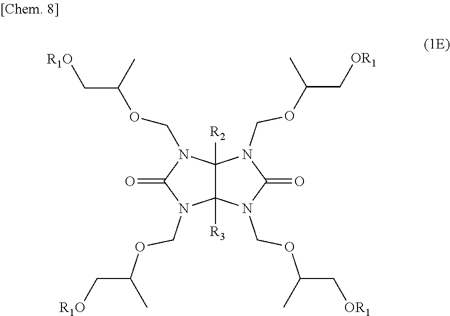

wherein, in formula (1E), the four R₁s each independently denote a methyl group or an ethyl group; and R₂ and R₃ each independently denote a hydrogen atom, a C1-C4 alkyl group, or a phenyl group.

Examples of the glycoluril derivatives represented by formula (1E) include compounds represented by the following formulas (1E-1) to (1E-6):

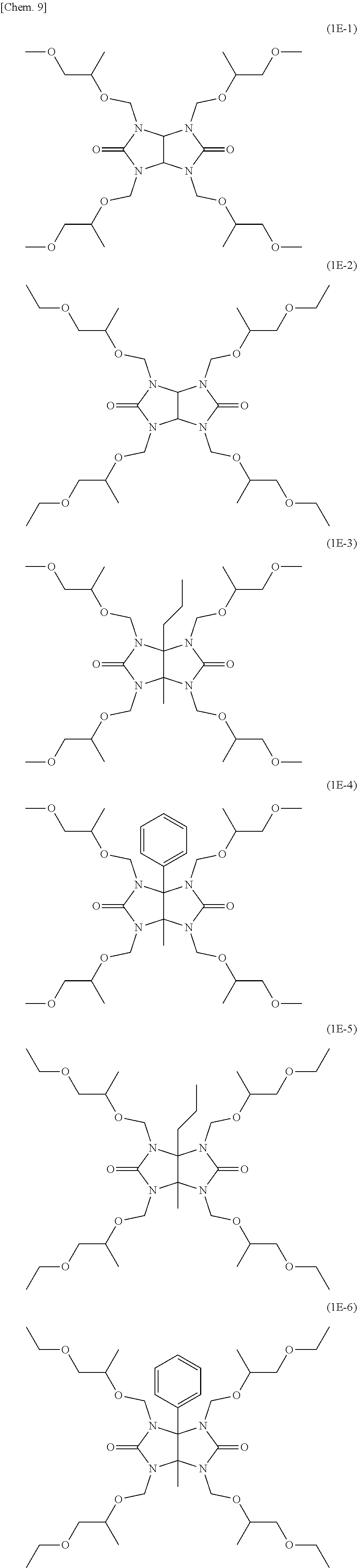

The nitrogen-containing compound that has in the molecule 2 to 6 substituents represented by formula (1d) is obtained by reacting a nitrogen-containing compound that has in the molecule 2 to 6 substituents represented by formula (2d) below which are bonded to nitrogen atoms, with at least one compound represented by formula (3d) below.

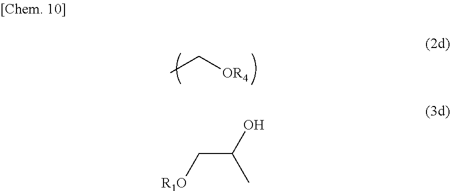

wherein, in formula (2d) and formula (3d), R₁ denotes a methyl group or an ethyl group; and R₄ denotes a C1-C4 alkyl group.

The glycoluril derivative represented by formula (1E) is obtained by reacting a glycoluril derivative represented by formula (2E) below with at least one compound represented by the above formula (3d).

For example, the nitrogen-containing compound that has in the molecule 2 to 6 substituents represented by formula (2d) is a glycoluril derivative represented by formula (2E) below:

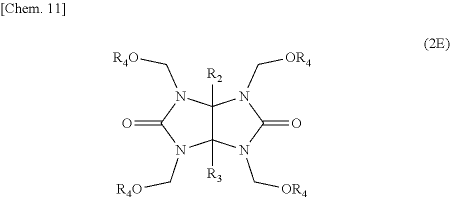

wherein, in formula (2E), R₂ and R₃ each independently denote a hydrogen atom, a C1-C4 alkyl group, or a phenyl group; and R₄, independently at each occurrence denotes a C1-C4 alkyl group.

Examples of the glycoluril derivatives represented by formula (2E) include compounds represented by formula (2E-1) to formula (2E-4) below. Furthermore, examples of the compounds represented by formula (3d) include compounds represented by formula (3d-1) and formula (3d-2) below.

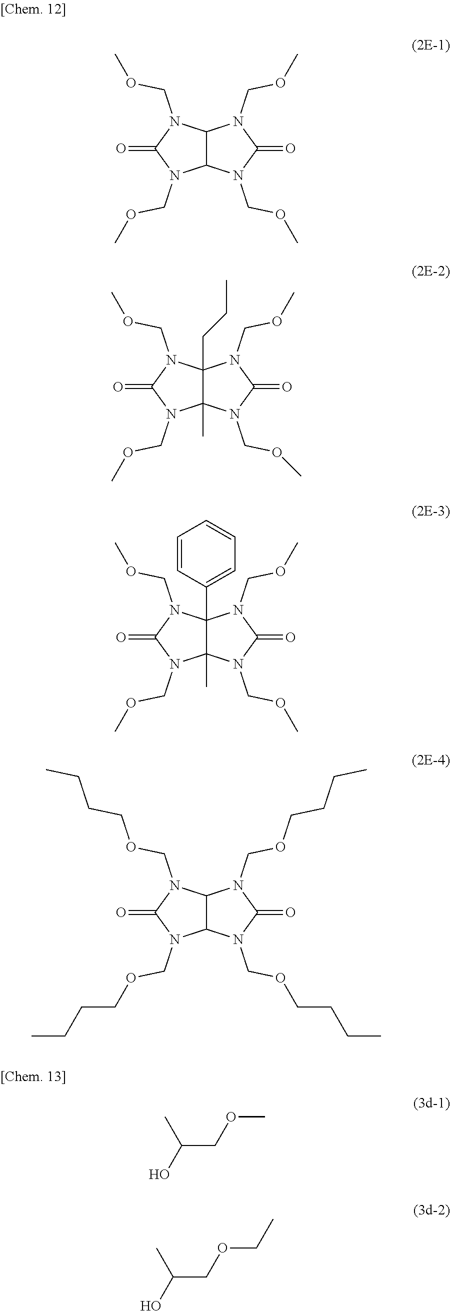

The nitrogen-containing compounds that have in the molecule 2 to 6 substituents represented by formula (1d) which are bonded to nitrogen atoms are disclosed in WO 2017/187969, the entire contents of which are incorporated herein by reference.

Furthermore, the crosslinking agent may be crosslinking compounds of formula (G-1) or formula (G-2) below described in WO 2014/208542.

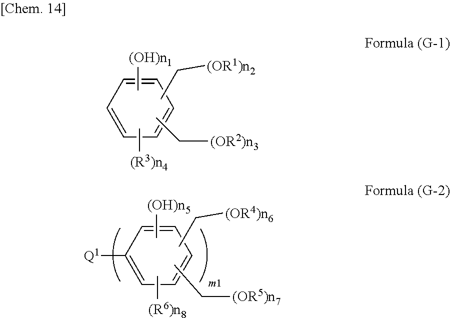

wherein, in the formulas, Q¹ denotes a single bond or an m1-valent organic group: R¹ and R⁴ each denote a C2-C10 alkyl group, or a C2-C10 alkyl group having a C1-C10 alkoxy group; R² and R⁵ each denote a hydrogen atom or a methyl group; and R³ and R⁶ each denote a C1-C10 alkyl group or a C6-C40 aryl group.
n1 is an integer of 1≤n1≤3: n2 is an integer of 2≤n2≤5 n3 is an integer of 0≤n3≤3; n4 is an integer of 0≤n4≤3; and 3≤(n1+n2+n3+n4)≤6.
n5 is an integer of 1≤n5≤3; n6 is an integer of 1≤n6≤4 n7 is an integer of 0≤n7≤3; n8 is an integer of 0≤n8≤3; and 2≤(n5+n6+n7+n8)≤5
m1 is an integer of 2 to 10.

The crosslinking compound represented by formula (G-1) or formula (G-2) may be a compound obtained by reacting a compound represented by formula (G-3) or formula (G-4) below with a hydroxy group-containing ether compound or a C2-C10 alcohol.

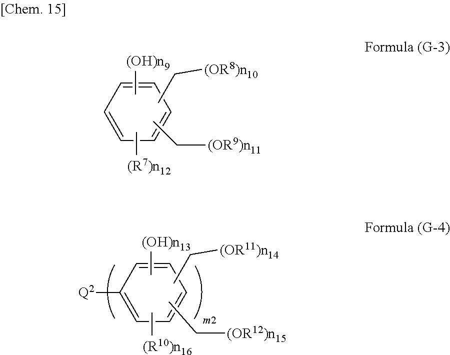

wherein, in the formulas, Q² denotes a single bond or an m2-valent organic group; R⁸, R⁹, R¹¹, and R¹² each denote a hydrogen atom or a methyl group; and R⁷ and R¹⁰ each denote a C1-C10 alkyl group or a C6-C40 aryl group.
n9 is an integer of 1≤n9≤3; n10 is an integer of 2≤n10≤5; n11 is an integer of 0≤n11≤3; n12 is an integer of 0≤n12≤3; and 3≤(n9+n10+n11+n12)≤6.
n13 is an integer of 1≤n13≤3; n14 is an integer of 1≤n14≤4; n15 is an integer of 0≤n15≤3; n16 is an integer of 0≤n16≤3; and 2≤(n13+n14+n15+n16)≤5.
m2 is an integer of 2 to 10.

Examples of the compounds represented by formula (G-1) and formula (G-2) include those illustrated below.

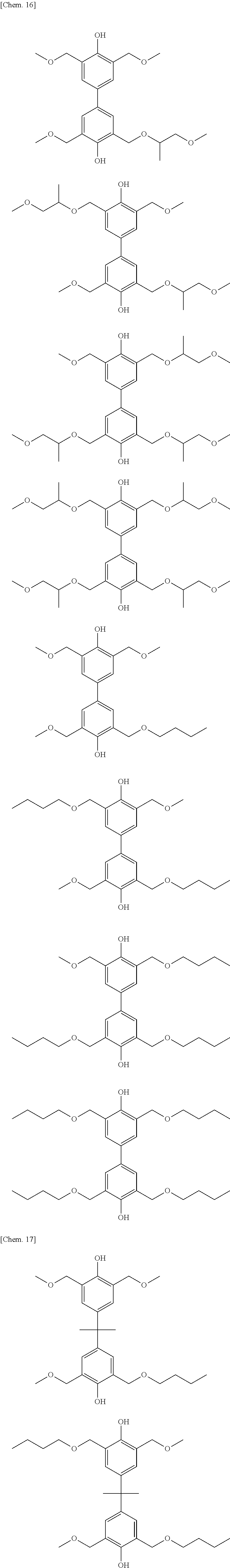

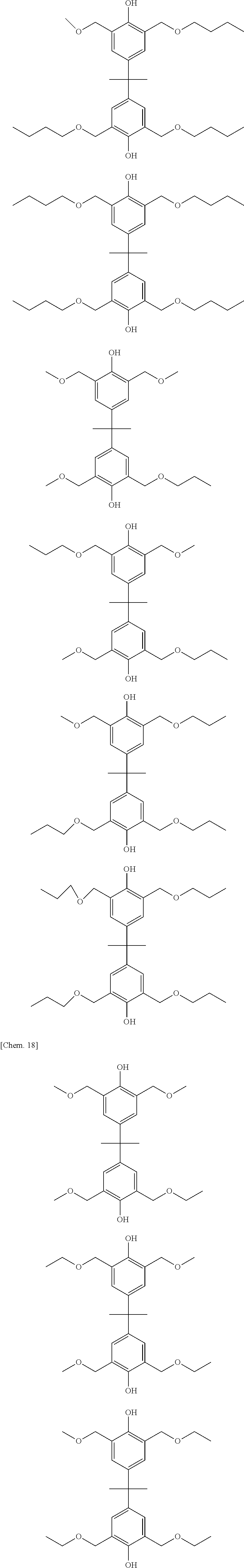

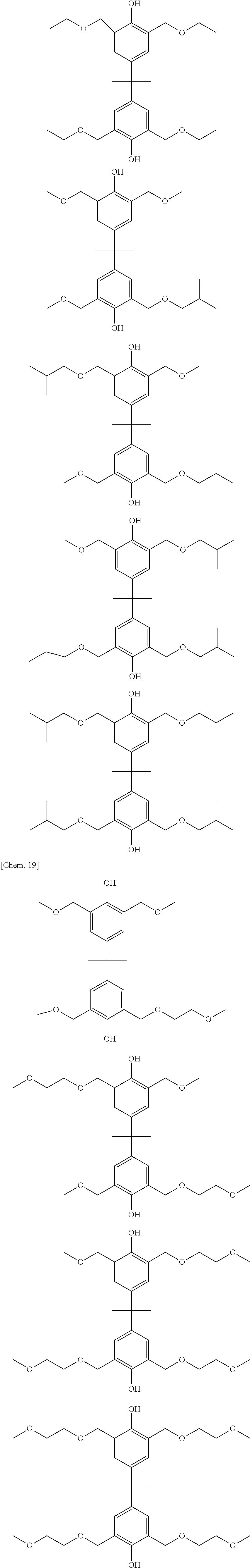

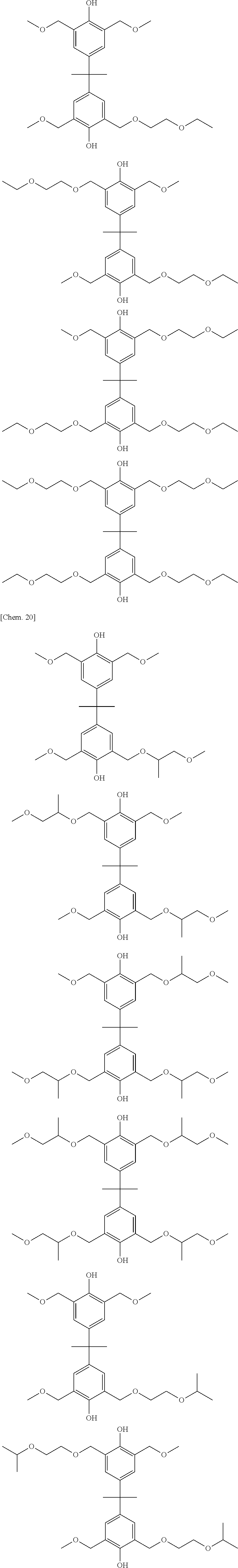

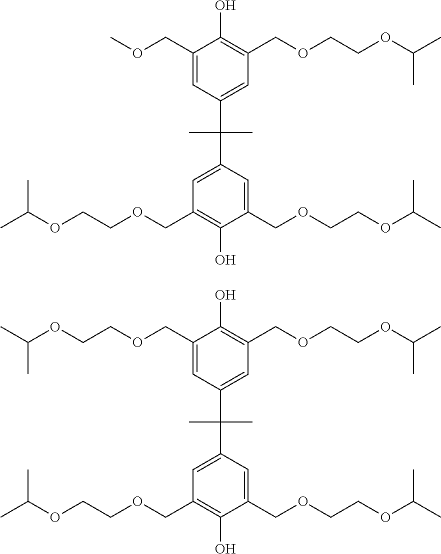

Examples of the compounds represented by formula (G-3) and formula (G-4) include those illustrated below.

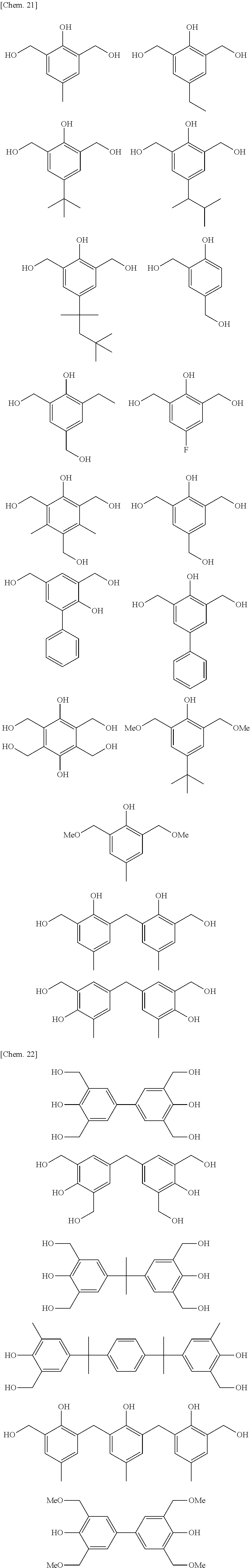

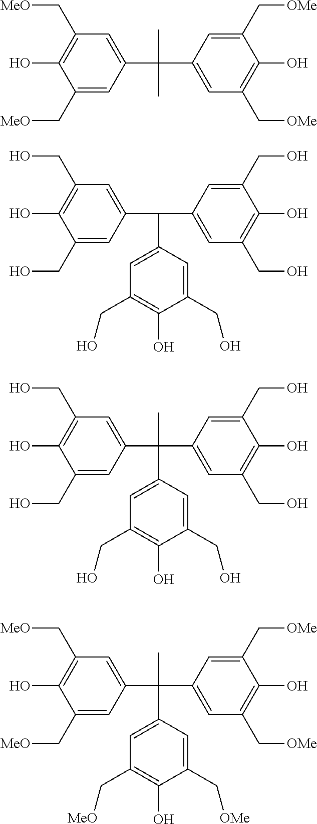

In the formulas, Me denotes a methyl group.

The entire contents of the disclosure of WO 2014/208542 are incorporated herein by reference.

When the crosslinking agent is used, the content of the crosslinking agent is, for example, within the range of 1% by mass to 50% by mass, and preferably 5% by mass to 30% by mass, relative to the reaction product.

### <Additional Component>

To eliminate the occurrence of defects, such as pinholes or striation, and to further enhance the applicability to surface unevenness, the resist underlayer film-forming composition of the present invention may further include a surfactant. Examples of the surfactants include nonionic surfactants, such as polyoxyethylene alkyl ethers including polyoxyethylene lauryl ether, polyoxyethylene stearyl ether, polyoxyethylene cetyl ether, and polyoxyethylene oleyl ether, polyoxyethylene alkylallyl ethers including polyoxyethylene octylphenol ether and polyoxyethylene nonylphenol ether, polyoxyethylene/polyoxypropylene block copolymers, sorbitan fatty acid esters including sorbitan monolaurate, sorbitan monopalmitate, sorbitan monostearate, sorbitan monooleate, sorbitan trioleate, and sorbitan tristearate, and polyoxyethylene sorbitan fatty acid esters including poly oxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorosurfactants, such as EFTOP series EF301, EF303, and EF352 (product names, manufactured by Tohkem Products Corp.), MEGAFACE series F171, F173, and R-30 (product names, manufactured by DIC CORPORATION), Fluorad series FC430 and FC431 (product names, manufactured by Sumitomo 3M Limited), AsahiGuard AG710, and Surflon series S-382, SC101, SC102, SC103, SC104, SC105, and SC106 (product names, manufactured by AGC Inc.); and organosiloxane polymer KP341 (manufactured by Shin-Etsu Chemical Co., Ltd.). The amount of the surfactant is usually 2.0% by mass or less, and preferably 1.0% by mass or less of the total solid content of the resist underlayer film-forming composition of the present invention. The surfactants may be added each alone or in combination of two or more thereof.

In the resist underlayer film-forming composition of the present invention, the solid content, specifically, the content of the components except the solvent is, for example, within the range of 0.01% by mass to 10% by mass.

### <Resist Underlayer Film>

A resist underlayer film of the present invention may be produced by applying the resist underlayer film-forming composition described hereinabove onto a semiconductor substrate and baking the applied composition.

Examples of the semiconductor substrates to which the resist underlayer film-forming composition of the present invention is applied include silicon wafers, germanium wafers, and compound semiconductor wafers, such as gallium arsenide, indium phosphide, gallium nitride, indium nitride, and aluminum nitride.

The semiconductor substrate that is used may have an inorganic film on its surface. For example, such an inorganic film is formed by ALD (atomic layer deposition), CVD (chemical vapor deposition), reactive sputtering, ion plating, vacuum deposition, or spin coating (spin on glass: SOG). Examples of the inorganic films include polysilicon films, silicon oxide films, silicon nitride films, BPSG (boro-phospho silicate glass) films, titanium nitride films, titanium oxynitride films, tungsten films, gallium nitride films, and gallium arsenide films.

The resist underlayer film-forming composition of the present invention is applied onto such a semiconductor substrate with an appropriate applicator, such as a spinner or a coater. Subsequently, the composition is baked with a heating device, such as a hot plate, to form a resist underlayer film. The baking conditions are appropriately selected from baking temperatures of 100° C. to 400° C. and amounts of baking time of 0.3 minutes to 60 minutes. Preferably, the baking temperature is 120° C. to 350° C. and the baking time is 0.5 minutes to 30 minutes. More preferably, the baking temperature is 150° C. to 300° C. and the baking time is 0.8 minutes to 10 minutes.

The film thickness of the resist underlayer film that is formed is, for example, within the range of 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm). If the baking temperature is lower than the range mentioned above, crosslinking is insufficient. If, on the other hand, the baking temperature is higher than the above range, the resist underlayer film may be decomposed by heat.

### <Method for Producing Patterned Substrate, and Method for Manufacturing Semiconductor Device>

A patterned substrate is produced through the following steps. Usually, a patterned substrate is produced by forming a photoresist layer on the resist underlayer film. The photoresist that is formed on the resist underlayer film by application and baking according to a method known per se is not particularly limited as long as the resist is sensitive to the light used for exposure. Any of negative photoresists and positive photoresists may be used, such as positive photoresists composed of a novolak resin and 1,2-naphthoquinonediazide sulfonic acid ester; chemically amplified photoresists composed of a photoacid generator and a binder having a group that is decomposed by an acid to increase the alkali dissolution rate; chemically amplified photoresists composed of an alkali-soluble binder, a photoacid generator, and a low-molecular compound that is decomposed by an acid to increase the alkali dissolution rate of the photoresist; chemically amplified photoresists composed of a photoacid generator, a binder having a group that is decomposed by an acid to increase the alkali dissolution rate, and a low-molecular compound that is decomposed by an acid to increase the alkali dissolution rate of the photoresist; and resists containing metal elements. Examples include V146G, product name, manufactured by JSR CORPORATION, APEX-E, product name, manufactured by Shipley, PAR710, product name, manufactured by Sumitomo Chemical Co., Ltd., and AR2772 and SEPR430, product names, manufactured by Shin-Etsu Chemical Co., Ltd Examples further include fluorine-containing polymer photoresists, such as those described in Proc. SPIE, Vol. 3999, 330-334 (2000), Proc. SPIE, Vol. 3999, 357-364 (2000), and Proc. SPIE, Vol. 3999, 365-374 (2000).

Furthermore, use may be made of, but not limited to, the so-called resist compositions and metal-containing resist compositions, such as resist compositions radiation-sensitive resin compositions, and high-resolution patterning compositions based on organic metal solutions described in, for example, WO 2019/188595, WO 2019/187881, NO 2019/187803, WO 2019/167737, WO 2019/167725, WO 2019/187445, WO 2019/167419, WO 2019/123842, WO 2019/054282, WO 2019/058945, WO 2019/058890, WO 2019/039290, WO 2019/044259, WO 2019/044231 WE) 2019/026549, WO 2018/193954, WO 2019/172054, WO 2019/021975, WO 2018/230334, WO 2018/194123, JP 2018-180525, WO 2018/190088, JP 2018-070596, JP 2018-028090, JP 2016-153409, JP 2016-130240, JP 2016-108325, JP 2016-047920, JP 2016-035570, JP 2016-035567, JP 2016-035565, JP 2019-101417, JP 2019-117373, JP 2019-052294, JP 2019-008280, JP 2019-008279, JP 2019-003176, JP 2019-003175, JP 2018-197853, JP 2019-191298, JP 2019-061217, JP 2018-045151 JP 2018-022039, JP 2016-090441, JP 2015-10878, JP 2012-168279, JP 2012-022261, JP 2012-022258, JP 2011-043749, JP 2010-181857, JP 2010-128369, WO 2018/031896, JP 2019-113855, WO 2017/156388, WE) 2017/066319, JP 2018-41099, WO 2016/065120, WO 2015/026482, JP 2016-29498, and JP 2011-253185.

Examples of the resist composition include the following compositions.

Active ray-sensitive or radiation-sensitive resin compositions that include a resin A which has a repeating unit containing an acid-decomposable group in which a polar group is protected by a protective group capable of being detached by the action of an acid, and a compound represented by the general formula (21).

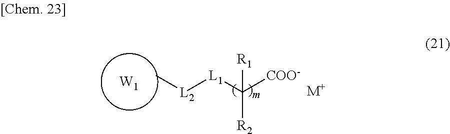

In the general formula (21), m denotes an integer of 1 to 6.

R₁ and R₂ each independently denote a fluorine atom or a perfluoroalkyl group.

L₁ denotes —O—, —S—, —COO—, —SO₂—, or —SO₃—.

L₂ denotes an optionally substituted alkylene group or a single bond.

W₁ denotes an optionally substituted cyclic organic group.

M⁺ denotes a cation.

Metal-containing film-forming compositions for extreme ultraviolet or electron beam lithography that include a compound having a metal-oxygen covalent bond, and a solvent. Here, the metal element constituting the compound belongs to Period 3 to Period 7 of Group 3 to Group 15 of the periodic table.

Radiation-sensitive resin compositions that include an acid generator, and a polymer which has a first structural unit represented by formula (31) below and a second structural unit of formula (32) below containing an acid-dissociative group.

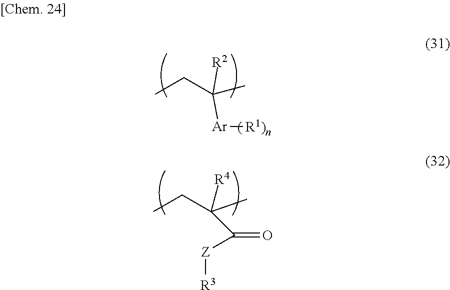

(In formula (31), Ar is a residue of a C6-C20 arene after removal of (n+1) hydrogen atoms. R¹ is a hydroxy group, a sulfanyl group, or a C1-C20 monovalent organic group. The letter n is an integer of 0 to 11. When n is 2 or greater, the groups R¹ are the same as or different from one another. R² is a hydrogen atom, a fluorine atom, a methyl group, or a trifluoromethyl group. In formula (32), R³ is a C1-C20 monovalent group including the acid-dissociative group. Z is a single bond, an oxygen atom, or a sulfur atom. R⁴ is a hydrogen atom, a fluorine atom, a methyl group, or a trifluoromethyl group.)

Resist compositions that include an acid generator, and a resin (A1) which contains a structural unit having a cyclic carbonate ester structure, a structural unit represented by formula (II), and a structural unit having an acid-labile group.

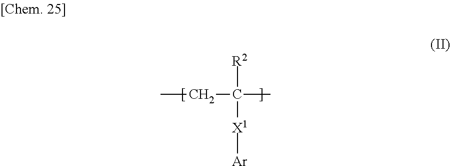

[In formula (II),
R² denotes an optionally halogenated C1-C6 alkyl group, a hydrogen atom, or a halogen atom, X¹ denotes a single bond, —CO—O—*, or —CO—NR⁴—*, * indicates a bond to —Ar, R⁴ denotes a hydrogen atom or a C1-C4 alkyl group, and Ar denotes a C6-C20 aromatic hydrocarbon group optionally having one or more groups selected from the group consisting of hydroxy group and carboxyl group.]

Examples of the resist films include the following.

Resist films that include a base resin which contains a repeating unit represented by formula (a1) below and/or a repeating unit represented by formula (a2) below, and a repeating unit which generates, upon exposure, an acid bonded to the polymer main chain.

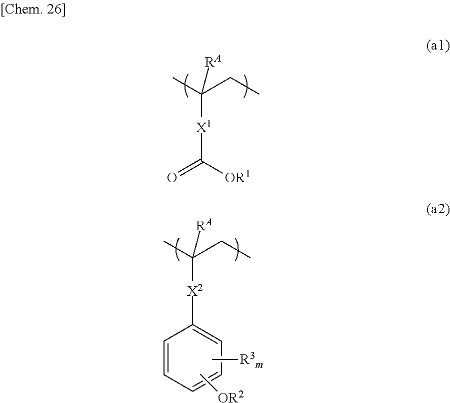

(In formula (a1) and formula (a2), R^{A} independently at each occurrence is a hydrogen atom or a methyl group. R¹ and R² are each independently a C4-C6 tertiary alkyl group. R³ independently at each occurrence is a fluorine atom or a methyl group. The letter m is an integer of 0 to 4. X¹ is a single bond, a phenylene group, or a naphthylene group, or is a C1-C12 linking group including at least one selected from ester bonds, lactone rings, phenylene groups, and naphthylene groups. X² is a single bond, an ester bond, or an amide bond.)

Examples of the resist materials include the following.

Resist materials that include a polymer which has a repeating unit represented by formula (b1) or formula (b2) below.

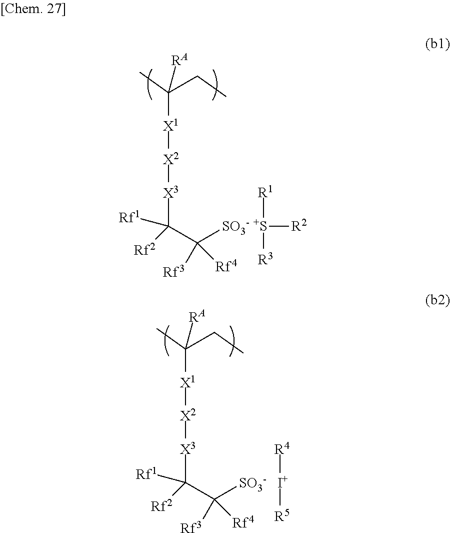

(In formula (b1) and formula (b2), R^{A} is a hydrogen atom or a methyl group. X is a single bond or an ester group. X² is a linear, branched, or cyclic C1-C12 alkylene group or a C6-C10 arylene group in which the alkylene group may be substituted with an ether group, an ester group, or a lactone ring-containing group in place of part of the methylene groups. X² is substituted with a bromine atom in place of at least one hydrogen atom. X³ is a single bond, an ether group, an ester group, or a C1-C12 linear, branched, or cyclic alkylene group optionally substituted with an ether group or an ester group in place of part of the methylene groups constituting the alkylene group. Rf¹ to Rf⁴ are each independently a hydrogen atom, a fluorine atom, or a trifluoromethyl group, and at least one is a fluorine atom or a trifluoromethyl group. Furthermore, Rf¹ and Rf² may be combined to form a carbonyl group. R¹ to R⁵ are each independently a linear, branched, or cyclic C1-C12 alkyl group, a linear, branched, or cyclic C2-C12 alkenyl group, a C2-C12 alkynyl group, a C6-C20 aryl group, a C7-C12 aralkyl group, or a C7-C12 aryloxyalkyl group, and each of these groups may be substituted with a hydroxy group, a carboxyl group, a halogen atom, an oxo group, a cyano group, an amide group, a nitro group, a sultone group, a sulfone group, or a sulfonium salt-containing group in place of part or all of the hydrogen atoms, and may be substituted with an ether group, an ester group, a carbonyl group, a carbonate group, or a sulfonic acid ester group in place of part of the methylene groups. Furthermore, R¹ and R² may be bonded to each other to form a ring together with the sulfur atom to which they are bonded.)

Resist materials that include a base resin which includes a polymer containing a repeating unit represented by formula (a) below.

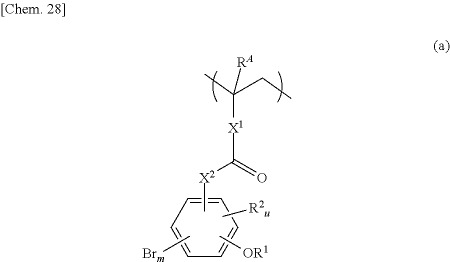

(In formula (a), R^{A} is a hydrogen atom or a methyl group. R¹ is a hydrogen atom or an acid-labile group. R² is a linear, branched, or cyclic C1-C6 alkyl group or a halogen atom other than bromine. X¹ is a single bond or a phenylene group, or is a linear, branched, or cyclic C1-C12 alkylene group optionally containing an ester group or a lactone ring. X² is —O—, —O—CH—, or —NH—. The letter nm is an integer of 1 to 4. The letter n is an integer of 0 to 3.)

Resist compositions that generate an acid upon exposure and change their solubility in a developer by the action of the acid.

The above resist compositions include a substrate component (A) that changes the solubility in a developer by the action of an acid, and a fluorine additive component (F) that exhibits decomposability in an alkaline developer.

The fluorine additive component (F) comprises a fluororesin component (F1) that contains a constituent unit (f1) containing a base-dissociative group, and a constituent unit (f2) containing a group represented by the general formula (f2-r-1) below.

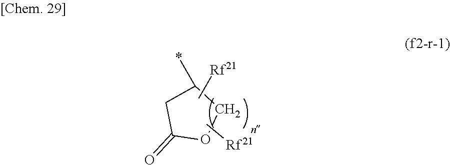

[In formula (f2-r-1), Rf²¹ independently at each occurrence is a hydrogen atom, an alkyl group, an alkoxy group, a hydroxy group, a hydroxy alkyl group, or a cyano group.

The letter n″ is an integer of 0 to 2. * is a bond.]

The constituent unit (f1) comprises a constituent unit represented by the general formula (f1-1) below or a constituent unit represented by the general formula (f1-2) below.

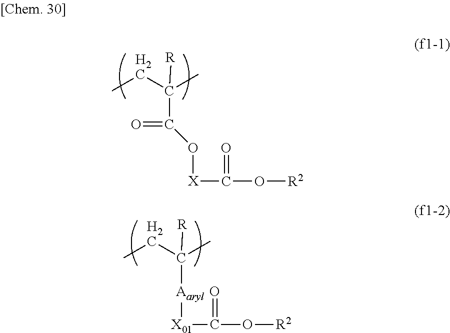

[In the formulas (f1-1) and (f1-2), R independently at each occurrence is a hydrogen atom, a C1-C5 alkyl group, or a Ct-C5 alkyl halide group. X is a divalent linking group having no acid-dissociative sites. A_{aryl} is an optionally substituted, divalent aromatic cyclic group. X₀₁ is a single bond or a divalent linking group. R² independently at each occurrence is an organic group having a fluorine atom.]

Examples of the coatings, the coating solutions, and the coating compositions include the following.

Coatings that include a metal oxo-hydroxo network which has an organic ligand through a metal-carbon bond and/or a metal-carboxylate bond.

Inorganic oxo/hydroxo-based compositions.

Coating solutions that include an organic solvent; a first organic metal composition which is represented by the formula R_{z}SnO_{(2-(z/2)-(x/2))}(OH)ₓ (where 0<z≤2 and 0<(z+x)≤4) or the formula R′ₙSnX₄₋ₙ (where n=1 or 2) or is a mixture thereof wherein R and R′ are independently a C1-C31 hydrocarbyl group, and X is a ligand having a hydrolyzable bond to Sn or is a combination of such ligands; and a hydrolyzable metal compound represented by the formula MX, (where M is a metal selected from Group 2 to Group 16 of the periodic table of the elements, v=a number of 2 to 6, and X′ is a ligand having a hydrolyzable M-X bond or is a combination of such ligands).

Coating solutions that include an organic solvent and a first organic metal compound represented by the formula RSnO_{(3/2-x/2)}(OH)ₓ (where 0<x<3) wherein the solution contains about 0.0025 M to about 1.5 M of tin, R is a C3-C31 alkyl or cycloalkyl group, and the alkyl or cycloalkyl group is bonded to tin through its secondary or tertiary carbon atom.

Inorganic pattern-forming precursor aqueous solutions that include a mixture of water, a metal suboxide cation, a polyatomic inorganic anion, and a radiation-sensitive ligand containing a peroxide group.

Exposure or irradiation is performed using, for example, i-ray, KrF excimer laser beam, ArF excimer laser beam, EUV (extreme ultraviolet ray), or EB (electron beam) through a mask (a reticle) designed to form a predetermined pattern, EB (electron beam) or EUV (extreme ultraviolet ray) is preferably used for the exposure of the resist underlayer film-forming composition of the subject application. EUV (extreme ultraviolet ray) is preferably used for the exposure. An alkaline developer is used for the development, and the conditions are appropriately selected from development temperatures of 5° C. to 50° C. and amounts of development time of 10 seconds to 300 seconds. Examples of the alkaline developers that may be used include aqueous solutions of alkalis, such as inorganic alkalis including sodium hydroxide, potassium hydroxide, sodium carbonate, sodium silicate, sodium metasilicate, and aqueous ammonia, primary amines including ethylamine and n-propylamine, secondary amines including diethylamine and di-n-butylamine, tertiary amines including triethylamine and methyldiethylamine, alcohol amines including dimethylethanolamine and triethanolamine, quaternary ammonium salts including tetramethylammonium hydroxide, tetraethylammonium hydroxide, and choline, and cyclic amines including pyrrole and piperidine. Appropriate amounts of alcohol, such as isopropyl alcohol, and surfactant, such as nonionic surfactants, may be added to the aqueous alkali solution described above. Of the developers mentioned above, quaternary ammonium salts are preferable, and tetramethylammonium hydroxide and choline are more preferable. Additional components, such as surfactant, may be added to the developer. An organic solvent, such as butyl acetate, may be used in place of the alkali developer to develop portions of the photoresist that remain low in alkali dissolution rate. A substrate having a pattern of the resist may be produced through the steps described above.

Next, the resist underlayer film is dry-etched using as a mask the resist pattern formed. When the inorganic film described hereinabove is present on the surface of the semiconductor substrate that is used, the surface of the inorganic film is exposed. When there is no inorganic film on the surface of the semiconductor substrate that is used, the surface of the semiconductor substrate is exposed. The substrate is then processed by a method known per se (such as a dry etching method). A semiconductor device may be thus manufactured.

### EXAMPLES

The present invention will be described in more detail by presenting Examples below without limiting the scope of the present invention thereto.

The weight average molecular weight of polymers described in Synthesis Examples and Comparative Synthesis Examples in the present specification is the results measured by gel permeation chromatography (hereinafter, abbreviated as GPC). The measurement was performed using a GPC device manufactured by TOSOH CORPORATION under the following measurement conditions.

GPC columns: Shodex KF803L, Shodex KF802, and Shodex KF801 [registered trademark] (SHOWA DENKO K.K.)
Column temperature: 40° C.
Solvent: Tetrahydrofuran (THF)
Flow rate: 1.0 ml/min
Standard samples: Polystyrenes (manufactured by TOSOH CORPORATION)

### Synthesis Example 1

2.00 g (% by mole relative to the whole polymer: 10% by mole, the same applies hereinafter) of 2-hydroxypropyl methacrylate (manufactured by Tokyo Chemical Industry Co., Ltd.), 16.32 g (% by mole relative to the whole polymer: 50% by mole) of adamantane methacrylate (manufactured by Tokyo Chemical Industry Co., Ltd.), 7.89 g (% by mole relative to the whole polymer: 40% by mole) of glycidyl methacrylate (manufactured by Tokyo Chemical Industry Co., Ltd.), and 1.14 g of azobisisobutyronitrile (manufactured by Tokyo Chemical Industry Co, Ltd.) were added and dissolved into 109.39 g of propylene glycol monomethyl ether. The reaction vessel was purged with nitrogen and the reaction was performed at 110° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 5,700 relative to standard polystyrenes, and a degree of dispersion of 2.21. The polymer obtained in this synthesis example has structural units represented by the following formulas (1a), (2a), and (1 b).

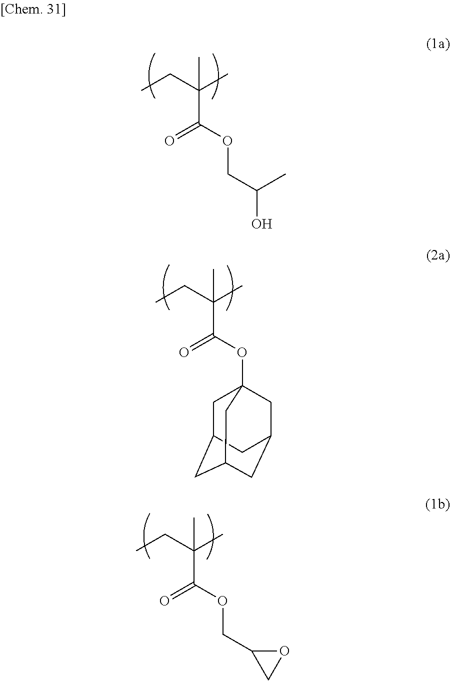

### Synthesis Example 2

30.00 g of the polymer solution including the polymer from Synthesis Example 1, 1.56 g (% by mole relative to the whole polymer: 40% by mole) of adamantanecarboxylic acid (manufactured by Tokyo Chemical Industry Co., Ltd.), and 0.06 g of tetrabutylphosphonium bromide (manufactured by ACROSS) were added and dissolved into 12.89 g of propylene glycol monomethyl ether. The reaction vessel was purged with nitrogen and the reaction was performed at 105° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 9,800 relative to standard polystyrenes, and a degree of dispersion of 2.71. The polymer obtained in this synthesis example has structural units represented by the following formulas (1a), (2a), and (2b).

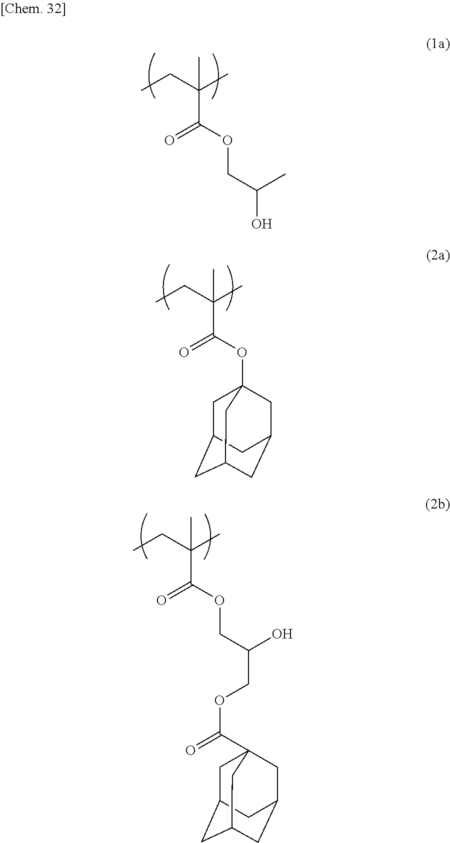

### Synthesis Example 3

7.00 g (% by mole relative to the whole polymer: 50% by mole) of adamantane methacrylate (manufactured by Tokyo Chemical Industry Co., Ltd.), 11.59 g (% by mole relative to the whole polymer: 50% by mole) of glycidyl methacrylate (manufactured by Tokyo Chemical Industry Co., Ltd.), and 0.81 g of azobisisobutyronitrile (manufactured by Tokyo Chemical Industry Co., Ltd.) were added and dissolved into 77.57 g of propylene glycol monomethyl ether. The reaction vessel was purged with nitrogen and the reaction was performed at 110° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 3,800 relative to standard polystyrenes, and a degree of dispersion of 1.60. The polymer obtained in this synthesis example has structural units represented by the following formulas (2a) and (1b).

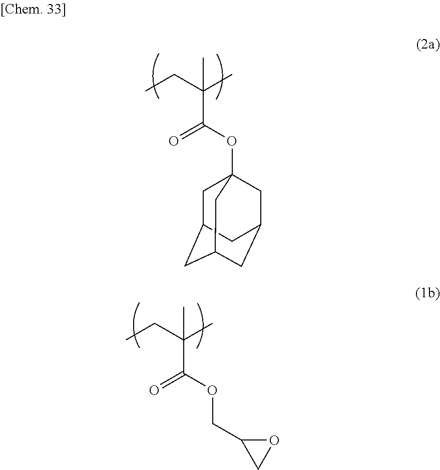

### Synthesis Example 4

30.00 g of the polymer solution including the polymer from Synthesis Example 3, 2.86 g (% by mole relative to the whole polymer: 50% by mole) of adamantanecarboxylic acid (manufactured by Tokyo Chemical Industry Co., Ltd.), and 0.12 g of tetrabutylphosphonium bromide (manufactured by ACROSS) were added and dissolved into 3.12 g of propylene glycol monomethyl ether. The reaction vessel was purged with nitrogen and the reaction was performed at 105° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 6,800 relative to standard polystyrenes, and a degree of dispersion of 2.42. The polymer obtained in this synthesis example has structural units represented by the following formulas (2a) and (2b).

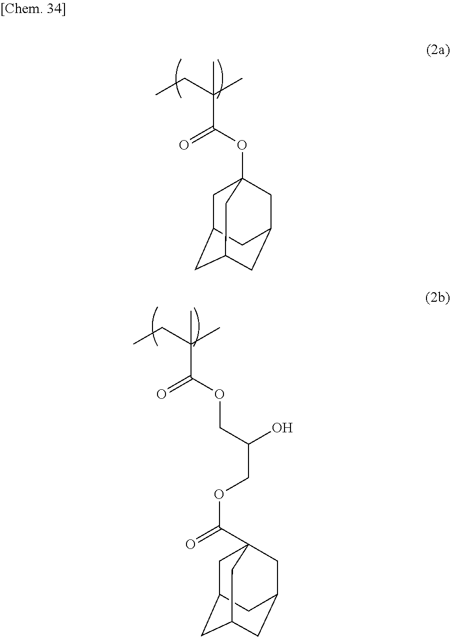

### Synthesis Example 5

7.00 g (% by mole relative to the whole polymer: 25% by mole) of 2-hydroxypropyl methacrylate (manufactured by Tokyo Chemical Industry Co., Ltd.), 22.85 g (% by mole relative to the whole polymer: 50% by mole) of adamantane methacrylate (manufactured by Tokyo Chemical Industry Co., Ltd.), 6.90 g (% by mole relative to the whole polymer: 25% by mole) of glycidyl methacrylate (manufactured by Tokyo Chemical Industry Co., Ltd.), and 1.59 g of azobisisobutyronitrile (manufactured by Tokyo Chemical Industry Co., Ltd.) were added and dissolved into 153.38 g of propylene glycol monomethyl ether. The reaction vessel was purged with nitrogen and the reaction was performed at 110° C. for 24 hours to yield a polymer solution. The polymer solution was free from clouding and other changes, even after being cooled to room temperature showing a good solubility in propylene glycol monomethyl ether. GPC analysis showed that the polymer in the solution obtained had a weight average molecular weight of 4,300 relative to standard polystyrenes, and a degree of dispersion of 2.34. The polymer obtained in this synthesis example has structural units represented by the following formulas (1a) (2a), and (1b).

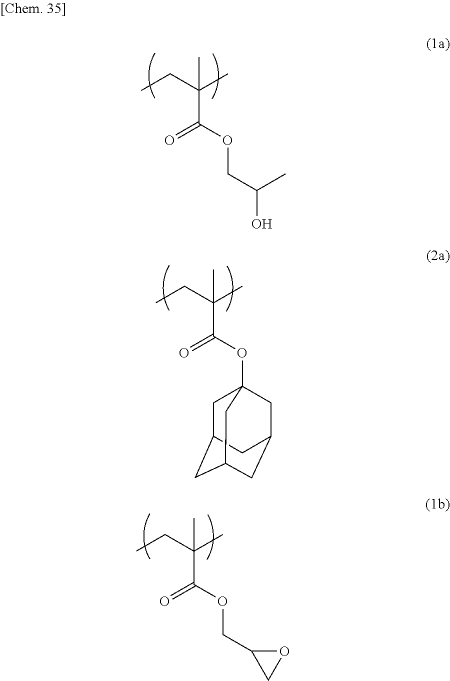

### Synthesis Example 6

25.00 g of the polymer solution including the polymer from Synthesis Example 5, 1.66 g (% by mole relative to the whole polymer: 25% by mole) of 4-methylsulfonebenzoic acid (manufactured by Tokyo Chemical Industry Co., Ltd.), and 0.06 g of tetrabutylphosphonium bromide (manufactured by ACROSS) were added and dissolved into 41.64 g of propylene glycol monomethyl ether. The reaction vessel was purged with nitrogen and the reaction was performed at 90° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 6,200 relative to standard polystyrenes, and a degree of dispersion of 2.31. The polymer obtained in this synthesis example has structural units represented by the following formulas (1a), (2a), and (3b).

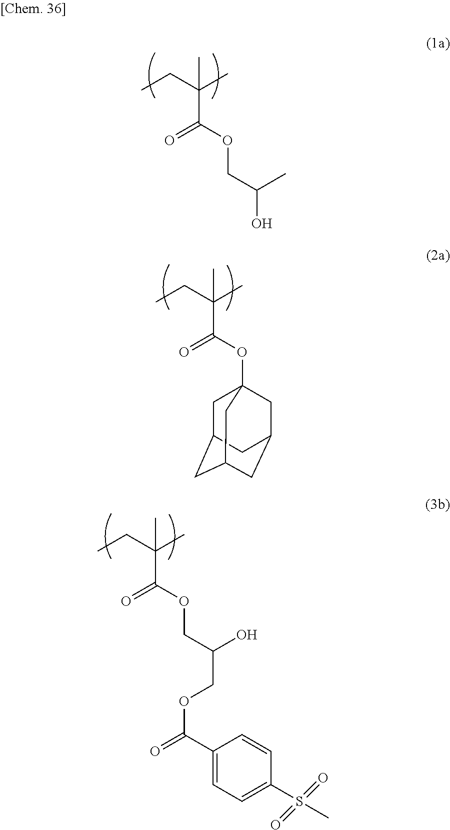

### Synthesis Example 7

25.00 g of the polymer solution including the polymer from Synthesis Example 5, 1.66 g (% by mole relative to the whole polymer: 25′% by mole) of benzoic acid (manufactured by Tokyo Chemical Industry Co., Ltd.), and 0.06 g of tetrabutylphosphonium bromide (manufactured by ACROSS) were added and dissolved into 41.64 g of propylene gly col monomethyl ether. The reaction vessel was purged with nitrogen and the reaction was performed at 90° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 6,300 relative to standard polystyrenes, and a degree of dispersion of 2.13. The polymer obtained in this synthesis example has structural units represented by the following formulas (1a), (2a), and (4b).

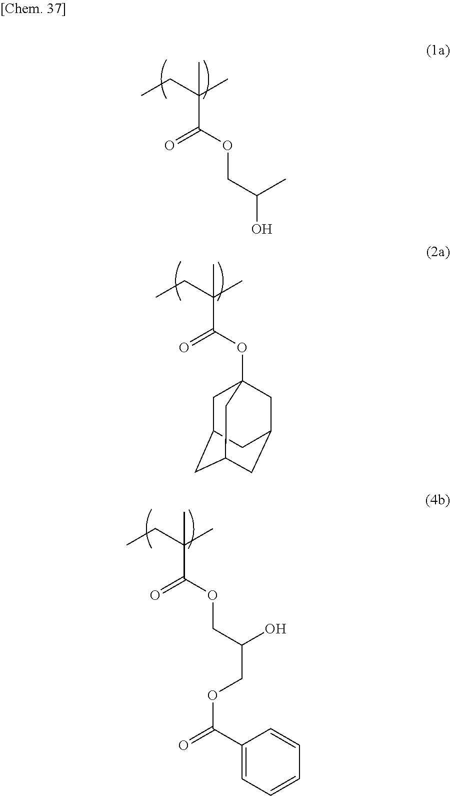

### Comparative Synthesis Example 1

6.58 g (% by mole relative to the whole polymer: 50% by mole) of 2-hydroxypropyl methacrylate (manufactured by Tokyo Chemical Industry Co., Ltd.), 10.00 g (% by mole relative to the whole polymer: 50% by mole) of adamantane methacrylate (manufactured by Tokyo Chemical Industry Co., Ltd.), and 0.60 g of azobisisobutyronitrile (manufactured by Tokyo Chemical Industry Co., Ltd.) were added and dissolved into 68.72 g of propylene glycol monomethyl ether. The reaction vessel was purged with nitrogen and the reaction was performed at 100° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 7,400 relative to standard polystyrenes and a degree of dispersion of 2.20. The polymer obtained in this synthesis example has structural units represented by the following formulas (1a) and (2a).

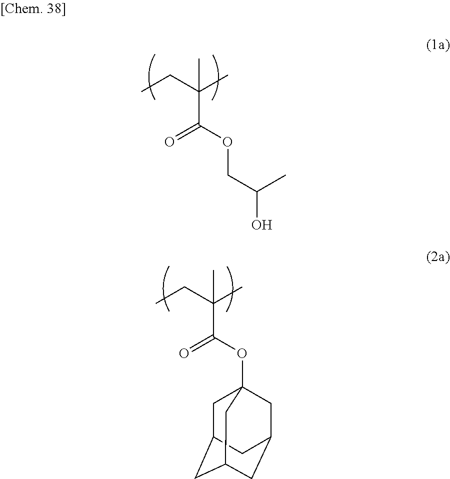

### Comparative Synthesis Example 2

5.00 g (% by mole relative to the whole polymer: 30% by mole) of 2-hydroxypropyl methacrylate (manufactured by Tokyo Chemical Industry Co., Ltd.), 17.82 g (% by mole relative to the whole polymer: 70% by mole) of adamantane methacrylate (manufactured by Tokyo Chemical Industry Co., Ltd.), and 0.95 g of azobisisobutyronitrile (manufactured by Tokyo Chemical Industry Co., Ltd.) were added and dissolved into 55.48 g of propylene glycol monomethyl ether. The reaction vessel was purged with nitrogen and the reaction was performed at 110° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 5,500 relative to standard polystyrenes, and a degree of dispersion of 1.62. The polymer obtained in this synthesis example has structural units represented by the following formulas (1a) and (2a)

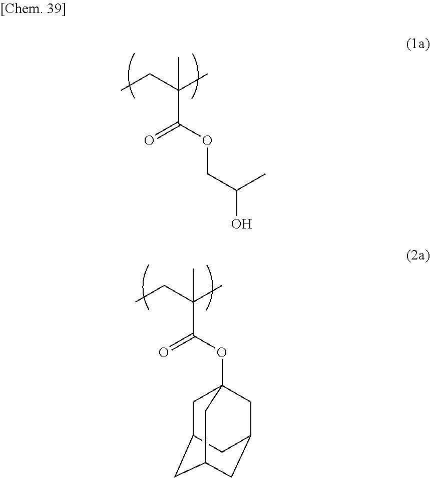

### Comparative Synthesis Example 3

5.49 g (% by mole relative to the whole polymer: 34% by mole) of 2-hydroxypropyl methacrylate (manufactured by Tokyo Chemical Industry Co., Ltd.), 8.40 g (% by mole relative to the whole polymer: 33% by mole) of adamantane methacrylate (manufactured by Tokyo Chemical Industry Co., Ltd.), 7.00 g (% by mole relative to the whole polymer: 33% by mole) of hydroquinone methacrylate (manufactured by FUJIFILM Wako Pure Chemical Corporation), and 0.95 g of azobisisobutyronitrile (manufactured by Tokyo Chemical Industry Co., Ltd.) were added and dissolved into 50.97 g of propylene glycol monomethyl ether. The reaction vessel was purged with nitrogen and the reaction was performed at 80° C. for 24 hours to yield a polymer solution. The polymer solution was free from clouding and other changes, even after being cooled to room temperature, showing a good solubility in propylene glycol monomethyl ether. GPC analysis showed that the polymer in the solution obtained had a weight average molecular weight of 14,000 relative to standard polystyrenes, and a degree of dispersion of 4.21. The polymer obtained in this synthesis example has structural units represented by the following formulas (1a), (2a), and (3a).

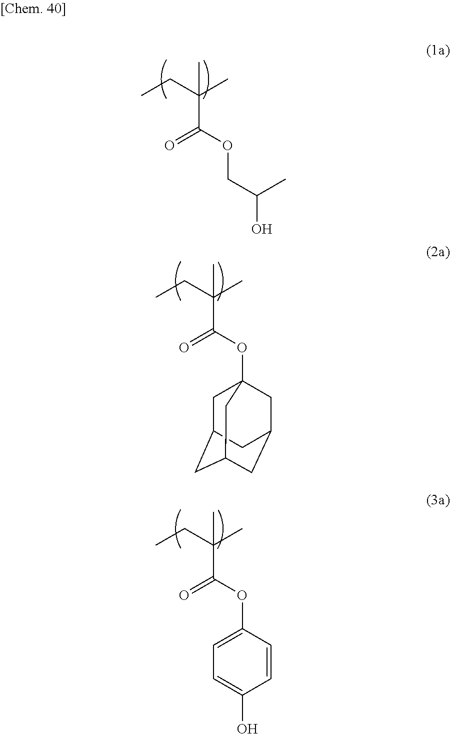

### <Preparation of Resist Underlayer Film-Forming Compositions>

### Examples

Each of the polymers from Synthesis Example 2, Synthesis Example 4, Synthesis Example 6, Synthesis Example 7, Comparative Synthesis Example 1, Comparative Synthesis Example 2, and Comparative Synthesis Example 3, and a crosslinking agent, a curing catalyst, and solvents were mixed in proportions shown in Tables 1 and 2. The mixture was filtered through a 0.1 μm fluororesin filter Resist underlayer film-forming composition was thus prepared in the form of a solution. In Tables 1 and 2, imidazo[4,5-d]imidazole-2,5(1H,3H)-dione, tetrahydro-1,3,4,6-tetrakis[(2-methoxy-1-methylethoxy)methyl]- is abbreviated as PGME-PL, pyridinium-p-hydroxybenzenesulfonic acid as PyPSA, propylene glycol monomethyl ether acetate as PGNMEA, and propylene glycol monomethyl ether as PGME. The amounts are shown in parts by mass.

TABLE 1

| Examples | Polymer | PGME-PL | PyPSA | PGME | PGMEA |
|---|---|---|---|---|---|
| Example 1 | Synthesis | 0.04 | 0.01 | 90 | 10 |
| | Example 2 | | | | |
| | 0.15 | | | | |
| Example 2 | Synthesis | 0.04 | 0.01 | 90 | 10 |
| | Example 4 | | | | |
| | 0.15 | | | | |
| Example 3 | Synthesis | 0.04 | 0.01 | 90 | 10 |
| | Example 6 | | | | |
| | 0.15 | | | | |
| Example 4 | Synthesis | 0.04 | 0.01 | 90 | 10 |
| | Example 7 | | | | |
| | 0.15 | | | | |

TABLE 2

| Examples | Polymer | PGME-PL | PyPSA | PGME | PGMEA |
|---|---|---|---|---|---|
| Comparative | Comparative | 0.04 | 0.01 | 90 | 10 |
| Example 1 | Synthesis | | | | |
| | Example 1 | | | | |
| | 0.15 | | | | |
| Comparative | Comparative | 0.04 | 0.01 | 90 | 10 |
| Example 2 | Synthesis | | | | |
| | Example 2 | | | | |
| | 0.15 | | | | |
| Comparative | Comparative | 0.04 | 0.01 | 90 | 10 |
| Example 3 | Synthesis | | | | |
| | Example 3 | | | | |
| | 0.15 | | | | |

[Test of Dissolution into Photoresist Solvents]

Each of the resist underlayer film-forming compositions of Examples 1 to 4 and Comparative Examples 1 to 3 was applied onto a silicon wafer as a semiconductor substrate using a spinner. The silicon wafer was set on a hot plate and the coating was baked at 205° C. for 1 minute to form a resist underlayer film (film thickness: 5 nm). The resist underlayer film was soaked in photoresist solvents, specifically, ethyl lactate and propylene glycol monomethyl ether. The resist underlayer films were insoluble in these solvents.

[Formation of Resist Patterns with Electron Beam Lithography System]

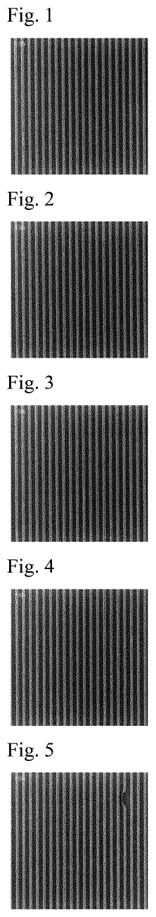

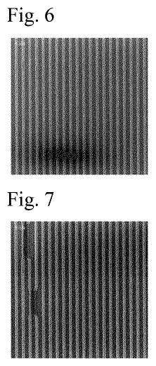

Each of the resist underlayer film-forming compositions of Examples 1 to 4 and Comparative Examples 1 to 3 was applied onto a silicon wafer using a spinner. The silicon wafer was baked on a hot plate at 205° C. for 60 seconds to form a resist underlayer film having a film thickness of 5 nm. Each of the resist underlayer films was spin-coated with an EUV positive resist solution (containing a methacrylic polymer), and the coating was heated at 130° C. for 60 seconds to form an EUV resist film. The resist film was exposed under the predetermined conditions using an electron beam lithography system (ELS-G130). After the exposure, baking (PEB) was performed at 100° C. for 60 seconds. The resist film was then cooled to room temperature on a cooling plate and was developed with an alkaline developer (2.38% TMAH), and subsequently a resist pattern having 22 nm line pattern/44 nm pitches was formed. The length measurement for the resist pattern was made with a scanning electron microscope (CG4100 manufactured by Hitachi High-Tech Corporation). The resist patterns formed above were evaluated as “good” when a line and space pattern with a CD size of 18 nm had been formed, and were rated as “defective” when the line and space pattern had collapsed or separated (Table 3). The results of observation from above the resist patterns with the electron microscope are illustrated in FIG. 1 to FIG. 7.

TABLE 3

| | 18 nm lines |
|---|---|
| Example 1 | Good |
| Example 2 | Good |
| Example 3 | Good |
| Example 4 | Good |
| Comparative Example 1 | Collapsed |
| Comparative Example 2 | Collapsed |
| Comparative Example 3 | Collapsed |

The resist underlayer film-forming composition according to the present invention is a composition for forming a resist underlayer film that allows a desired resist pattern to be formed. The resist underlayer film-forming composition is useful in a method for producing a resist-patterned substrate, and a method for manufacturing a semiconductor device.

1. A resist underlayer film-forming composition comprising a polymer and a solvent, the polymer comprising a unit structure (A) represented by formula (1) below and a unit structure (B) containing an aliphatic ring in a side chain and differing from the unit structure (A), 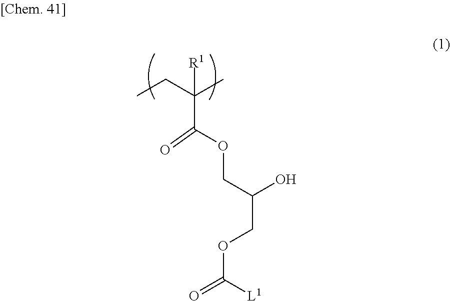
wherein, in formula (1), R¹ denotes a hydrogen atom or a C1-C6 alkyl group; and L¹ denotes an optionally substituted aliphatic ring, a C6-C40 aryl group, or a heterocyclic ring.

2. The resist underlayer film-forming composition according to claim 1, wherein the unit structure (B) is represented by formula (2) below: 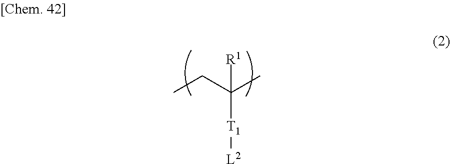
wherein, in formula (2), T₁ denotes a single bond, an amide bond, or an ester bond; and L² denotes an optionally substituted aliphatic ring.

3. The resist underlayer film-forming composition according to claim 1, wherein the polymer further comprises a unit structure (C) containing a reactive substituent.

4. The resist underlayer film-forming composition according to claim 1, wherein L¹ is an optionally substituted C3-C10 monocyclic or polycyclic aliphatic ring.

5. The resist underlayer film-forming composition according to claim 2, wherein L² is an optionally substituted C3-C10 monocyclic or polycyclic aliphatic ring.

6. The resist underlayer film-forming composition according to claim 1, further comprising an acid generator.

7. The resist underlayer film-forming composition according to claim 1, further comprising a crosslinking agent.

8. A resist underlayer film, which is a baked product of a coating film of the resist underlayer film-forming composition according to claim 1.

9. A method for producing a patterned substrate, comprising the steps of:
applying the resist underlayer film-forming composition according to claim 1 onto a semiconductor substrate and baking the applied composition to form a resist underlayer film;
applying a resist onto the resist underlayer film and baking the applied resist to form a resist film;
exposing the semiconductor substrate coated with the resist underlayer film and the resist; and
developing the exposed resist film, and performing patterning.

10. A method for manufacturing a semiconductor device, comprising the steps of:
forming on a semiconductor substrate a resist underlayer film of the resist underlayer film-forming composition according to claim 1;
forming a resist film on the resist underlayer film;
forming a resist pattern by applying a light or electron beam to the resist film followed by development;
forming a pattern in the resist underlayer film by etching the resist underlayer film through the resist pattern formed; and
processing the semiconductor substrate through the pattern in the resist underlayer film.
